(19) United States
(12) Patent Application Publication
(10) Pub. No.: US 2024/0206299 A1
(43) Pub. Date: Jun. 20, 2024

(54) DISPLAY DEVICE

(71) Applicant: Samsung Display Co., Ltd., Yongin-si (KR)

(72) Inventors: Oh Jeong KWON, Yongin-si (KR); Seung Yeon JEONG, Yongin-si (KR); Tae Ho KIM, Yongin-si (KR); HYEOJI KANG, Yongin-si (KR); Hong Yeon LEE, Yongin-si (KR)

(21) Appl. No.: 18/503,104

(22) Filed: Nov. 6, 2023

(30) Foreign Application Priority Data
Dec. 5, 2022 (KR) 10-2022-0168012

(51) Int. Cl. H10K 59/80

(52) U.S. Cl. CPC H10K 59/8792; H10K 50/11

(57) ABSTRACT

A display device according to an embodiment includes: a substrate; and a plurality of light emitting devices disposed above the substrate. The light emitting device includes a first electrode, an auxiliary layer disposed above the first electrode, a light emitting layer disposed on the auxiliary layer, and a second electrode disposed above the light emitting layer, and a red light emitting layer and/or the auxiliary layer includes a discussed compound, e.g., a compound represented by Chemical Formula 1 and/or a compound represented by Chemical Formula 2.

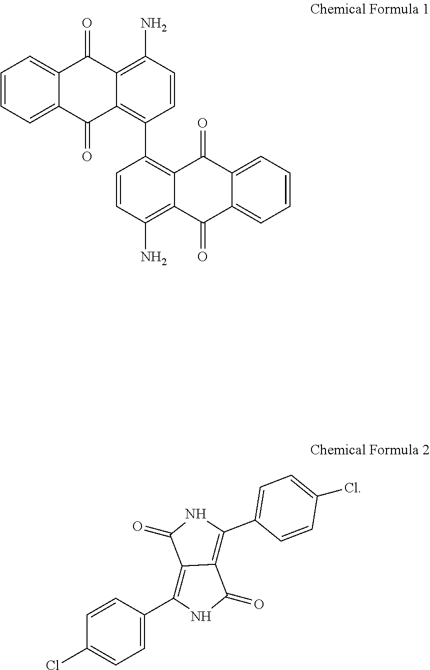 [SMILES: Nc1ccc(-c2ccc(N)c3c2C(=O)c2ccccc2C3=O)c2c1C(=O)c1ccccc1C2=O ; O=C1NC(c2ccc(Cl)cc2)=C2C(=O)NC(c3ccc(Cl)cc3)=C12]

### CROSS-REFERENCE TO RELATED APPLICATION

This application claims priority to and the benefit of Korean Patent Application No. 10-2022-0168012, filed in the Korean Intellectual Property Office on Dec. 5, 2022, the entire content of which is incorporated herein by reference.

### BACKGROUND

### 1. Field

The present disclosure relates to a display device, and for example, to a display device with reduced reflection (e.g., reflection of external light).

2. Description of the Related Art

When external light is reflected and/or scattered on a display surface of a display device, an original image on the display device may not be properly observed. For example, because a portable device such as a mobile phone, a laptop computer, and/or the like is increasingly being utilized outdoors where there may be an excess amount or there may be plenty of external light, a problem of the reflection and/or scattering of external light on the display surface of the display device should be be overcome.

Various suitable methods have been proposed to overcome the problem of the reflection and/or scattering of external light.

The above information disclosed in this Background section is only for enhancement of understanding of the background of the disclosure, and therefore it may contain information that does not form the prior art.

### SUMMARY

An aspect according to one or more embodiments of the present disclosure is directed toward a display device with reduced external light reflection.

Additional aspects will be set forth in part in the description which follows and, in part, will be apparent from the description, or may be learned by practice of the presented embodiments of the disclosure.

A display device according to an embodiment includes: a substrate; and a light emitting device on the substrate. The light emitting device includes a first electrode, a red auxiliary layer on the first electrode, a red light emitting layer on the red auxiliary layer, and a second electrode on the red light emitting layer, and the red light emitting layer and/or the red auxiliary layer includes a compound represented by Chemical Formula 1 and/or a compound represented by Chemical Formula 2.

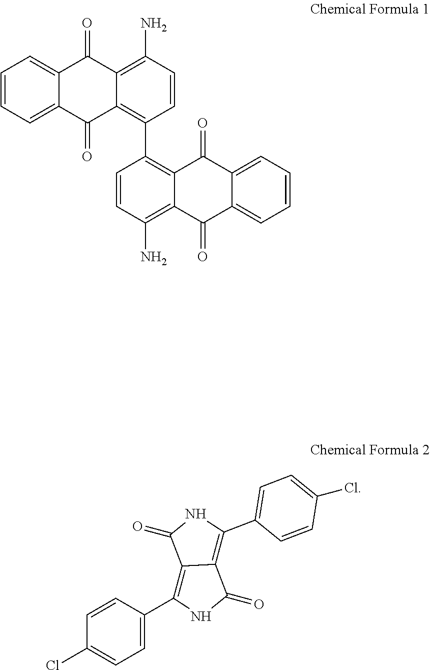 [SMILES: Nc1ccc(-c2ccc(N)c3c2C(=O)c2ccccc2C3=O)c2c1C(=O)c1ccccc1C2=O ; O=C1NC(c2ccc(Cl)cc2)=C2C(=O)NC(c3ccc(Cl)cc3)=C12]

A content (e.g., amount) of the compound represented by Chemical Formula 1 and/or the compound represented by Chemical Formula 2 in the red light emitting layer and/or the red auxiliary layer may be 1 wt % to 50 wt % based on a total weight of the red light emitting layer and/or the red auxiliary layer.

The light emitting device may further include: a capping layer on the second electrode; and an encapsulation layer on the capping layer.

The light emitting device may further include an inorganic absorption layer between the capping layer and the encapsulation layer and/or between the capping layer and the second electrode, and the inorganic absorption layer may include bismuth.

The display device may not include a (e.g., may exclude any) polarization layer (e.g., is free of polarization layer).

The display device may not include a (e.g., may exclude any) color filter (e.g., is free of color filter).

The display device may further include: a reflection control layer on the encapsulation layer; and a low-reflection inorganic layer on the light emitting device. The reflection control layer may include a pigment and/or a dye.

A display device according to another embodiment includes: a substrate; and a light emitting device on the substrate. The light emitting device includes a first electrode, a green auxiliary layer on the first electrode, a green light emitting layer on the green auxiliary layer, and a second electrode on the green light emitting layer, and the green light emitting layer and/or the green auxiliary layer includes at least one selected from among compounds represented by Chemical Formula 3 to Chemical Formula 6.

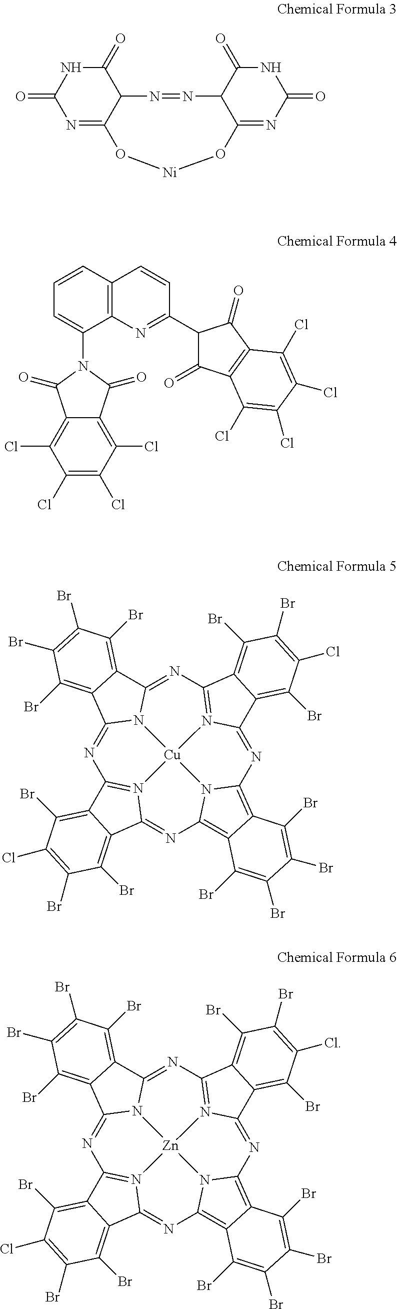

A content (e.g., amount) of the at least one selected from the compounds represented by Chemical Formula 3 to Chemical Formula 6, in the green light emitting layer and/or the green auxiliary layer, may be 1 wt % to 50 wt % based on a total weight of the green light emitting layer and/or the green auxiliary layer.

The light emitting device may further include: a capping layer on the second electrode; and an encapsulation layer on the capping layer.

The light emitting device may further include an inorganic absorption layer between the capping layer and the encapsulation layer or between the capping layer and the second electrode, and the inorganic absorption layer may include bismuth.

The display device may not include a (e.g., may exclude any) polarization layer (e.g., is free of polarization layer).

The display device may not include a (e.g., may exclude any) color filter (e.g., is free of color filter).

The display device may further include: a reflection control layer on the encapsulation layer; and a low-reflection inorganic layer on the light emitting device. The reflection control layer may include a pigment and/or a dye.

A display device according to another embodiment includes: a substrate; and a light emitting device on the substrate. The light emitting device includes a first electrode, a blue light emitting layer on the first electrode, and a second electrode on the blue light emitting layer, and the blue light emitting layer includes at least one selected from compounds represented by Chemical Formula 3, Chemical Formula 4, Chemical Formula 7, and Chemical Formula 8.

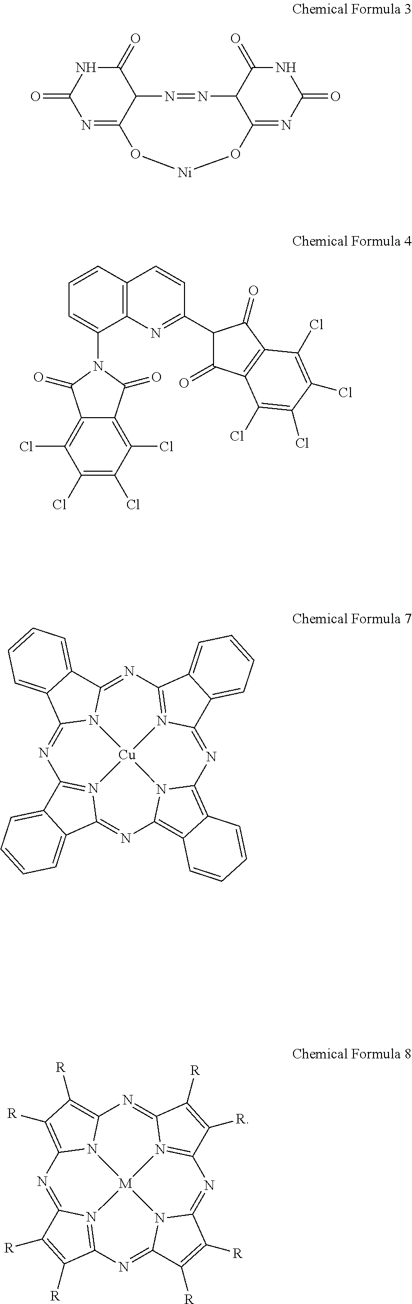

The at least one selected from the compounds represented by Chemical Formula 3, Chemical Formula 4, Chemical Formula 7, and Chemical Formula 8 may be 1 wt % to 50 wt % based on a total weight of the blue light emitting layer.

A display device according to another embodiment includes: a substrate; and a plurality of light emitting devices on the substrate. The plurality of light emitting devices include a first electrode, a hole control layer on the first electrode, a respective one of a red light emitting layer, a green light emitting layer, or a blue light emitting layer on the hole control layer, an electron control layer on the red light emitting layer, the green light emitting layer, and the blue light emitting layer, and a second electrode on the electron control layer, and the electron control layer or the hole control layer includes at least one selected from compounds represented by Chemical Formula 8 to Chemical Formula 11.

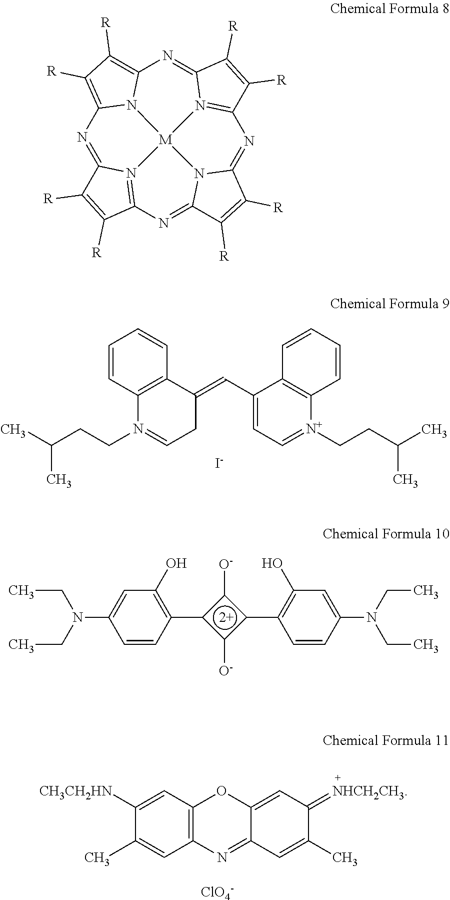

The at least one selected from compounds represented by Chemical Formula 8 to Chemical Formula 11 may be 1 wt % to 50 wt % based on a total weight of the electron control layer and/or the hole control layer.

A display device according to another embodiment includes: a substrate; and a plurality of light emitting devices on the substrate. The plurality of light emitting devices include a first electrode, a hole control layer on the first electrode, a red light emitting layer, a green light emitting layer, and a blue light emitting layer respectively disposed above or on the hole control layer, an electron control layer on the red light emitting layer, the green light emitting layer, and the blue light emitting layer, a second electrode on the electron control layer, a red auxiliary layer between the red light emitting layer and the hole control layer, and a green auxiliary layer between the green light emitting layer and the hole control layer The red auxiliary layer includes a compound represented by Chemical Formula 1, the green auxiliary layer includes a compound represented by Chemical Formula 3, and the blue light emitting layer includes a compound represented by Chemical Formula 8.

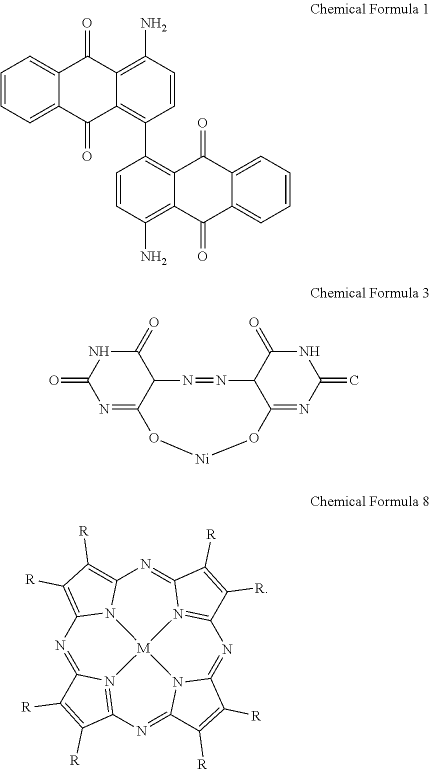

The display device may not include (e.g., may exclude) a polarization layer or a color filter (e.g., free of both polarization layer and color filter).

According to the embodiments, a display device having reduced external light reflection is provided.

### BRIEF DESCRIPTION OF THE DRAWINGS

The above and other aspects, features, and enhancements of certain embodiments of the disclosure will be more apparent from the following description taken in conjunction with the accompanying drawings, in which:

FIG. 1 schematically illustrates a cross-sectional view of a light emitting device (or a light emitting element) according to an embodiment.

FIG. 2 schematically illustrates a cross-sectional view of a light emitting device emitting red, blue, and green light.

FIG. 3 illustrates a light emission spectrum of a red light emitting device and an absorption spectrum (or a light absorption spectrum) of a compound represented by Chemical Formula 1.

FIG. 4 illustrates reflectance of the light emitting device according to a content (e.g., amount) of the compound of Chemical Formula 1 included in a red auxiliary layer.

FIG. 5 illustrates the light emitting device including an inorganic absorption layer between an encapsulation layer and a capping layer.

FIG. 6 shows the reflectance of the light emitting device according to the content (e.g., amount) of the compound of Chemical Formula 1 included in the red auxiliary layer in the light emitting device including the inorganic absorption layer shown in FIG. 5.

FIG. 7 shows reflectance of the light emitting device according to a content (e.g., amount) of a compound of Chemical Formula 3 included in a green auxiliary layer.

FIG. 8 shows reflectance of the light emitting device according to a content (e.g., amount) of a compound of Chemical Formula 7 included in a blue light emitting layer.

FIG. 9 illustrates reflectance of the light emitting device according to a content (e.g., amount) of a compound of Chemical Formula 8 included in a hole control layer.

FIG. 10 shows a cross-sectional view of a light emitting device according to another embodiment.

FIG. 11 is a comparison of optical characteristics of Embodiments 1 and 2 (or first and second embodiments).

FIG. 12 is a measurement of reflective colors of the Embodiments 1 and 2.

FIG. 13 shows the reflective colors of the Embodiments 1 and 2.

FIG. 14 schematically illustrates a cross-sectional view of a display device according to an embodiment.

FIG. 15 is a cross-sectional view of a display device according to another embodiment.

FIG. 16 shows a tandem structure in which light emitting devices are stacked.

### DETAILED DESCRIPTION

The present disclosure will be described more fully hereinafter with reference to the accompanying drawings, in which embodiments of the disclosure are shown. As those skilled in the art would realize, the described embodiments may be modified in one or more suitable different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present disclosure is not limited to those illustrated in the drawings. In the drawings, the thickness of layers, films, panels, regions, etc., and the areas may be exaggerated for clarity and for ease of description.

It will be understood that when an element such as a layer, film, region, area, or substrate is referred to as being “on” another element, it can be directly on the other element or intervening elements may also be present. In contrast, when an element is referred to as being “directly on” another element, there are no intervening elements present. Further, in the specification, the word “on” or “above” refers to positioned on or below the object portion, and does not necessarily refer to positioned on the upper side of the object portion based on a gravitational direction.

In addition, unless explicitly described to the contrary, the word “comprise” and variations such as “comprises” or “comprising” will be understood to imply the inclusion of the stated elements but not the exclusion of any other elements.

Further, throughout the specification, the phrase “in a plan view” or “on a plane” refers to viewing a target portion from the top, and the phrase “in a cross-sectional view” or “on a cross-section” refers to viewing a cross-section formed by vertically cutting a target portion from the side.

Hereinafter, a light emitting device (or a light emitting element) and a display device including the light emitting device according to the present embodiment will be described in more detail with reference to the drawings.

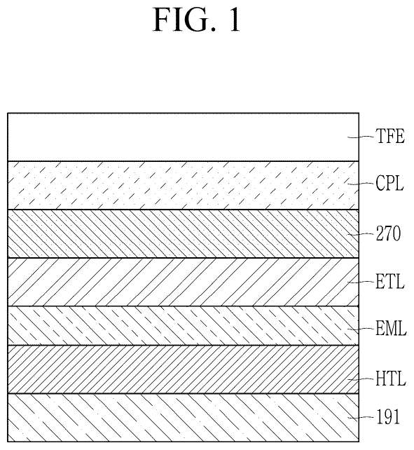

FIG. 1 schematically illustrates a cross-sectional view of the light emitting device according to the present embodiment. Referring to FIG. 1, the light emitting device according to the present embodiment includes a first electrode 191, a hole control layer HTL, a light emitting layer EML, an electron control layer ETL, a second electrode 270, a capping layer CPL, and an encapsulation layer TFE. According to embodiments of the present disclosure, a dye and/or a pigment having a light absorption characteristic is included in at least one of the hole control layer HTL, the light emitting layer EML, or the electron control layer ETL to reduce the reflectance of the display device (including the light emitting device) and to absorb external light. In an embodiment, the hole control layer HTL may include a hole injection layer and a hole transport layer. The electron control layer ETL may include an electron injection layer and an electron transport layer.

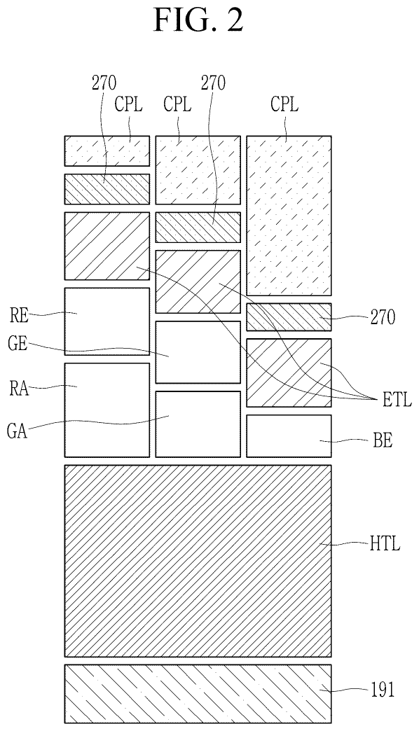

FIG. 2 schematically illustrates the cross-sectional view of the light emitting device emitting red, blue, and green light (e.g., a plurality of, or three light emitting devices for emitting red, blue, and green light, respectively). Referring to FIG. 2, the light emitting device (e.g., a plurality of, or three the light emitting devices) according to the present embodiment may include the first electrode 191, the hole control layer HTL, a red auxiliary layer RA, a red light emitting layer RE, a green auxiliary layer GA, a green light emitting layer GE, and a blue light emitting layer BE. The red auxiliary layer RA may be disposed between the red light emitting layer RE and the hole control layer HTL, and the green auxiliary layer GA may be disposed between the green light emitting layer GE and the hole control layer HTL.

The electron control layer ETL may be disposed above or on the red light emitting layer RE, the green light emitting layer GE, and the blue light emitting layer BE. The second electrode 270 may be disposed above or on the electron control layer ETL. The capping layer CPL may be disposed above or on the second electrode 270.

In the present embodiment, a light absorbing material may be disposed in an individual layer of the light emitting device for emitting light of each color (e.g., disposed in the red auxiliary layer RA or the green auxiliary layer GA). In some embodiments, the light absorbing material may be disposed in the hole control layer HTL or the electron control layer ETL commonly disposed in each light emitting device.

Various embodiments are described below in more detail.

In an embodiment, the red auxiliary layer RA or the red light emitting layer RE may include a red dye, and the red dye may be a compound represented by Chemical Formula 1 or Chemical Formula 2. In this case, a content (e.g., amount) of the red dye within the red auxiliary layer RA and/or the red light emitting layer RE may be 1 wt % to 50 wt % based on a total weight of the red auxiliary layer RA and/or the red light emitting layer RE including the red dye.

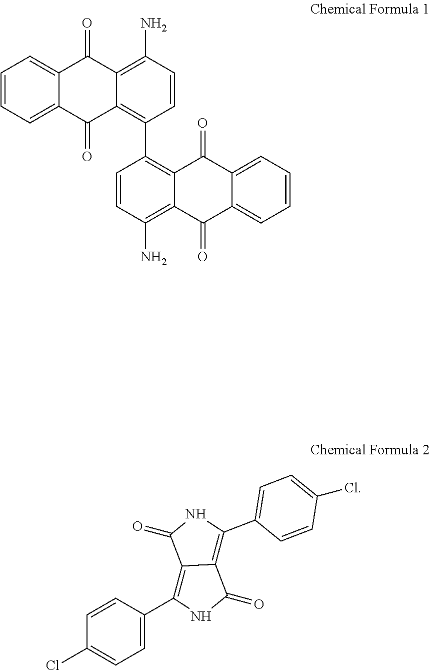 [SMILES: Nc1ccc(-c2ccc(N)c3c2C(=O)c2ccccc2C3=O)c2c1C(=O)c1ccccc1C2=O ; O=C1NC(c2ccc(Cl)cc2)=C2C(=O)NC(c3ccc(Cl)cc3)=C12]

Because the compound represented by Chemical Formula 1 or Chemical Formula 2 has an absorption coefficient for a red light emitting region close to 0, the reflectance of external light may be reduced without reducing the luminous efficiency.

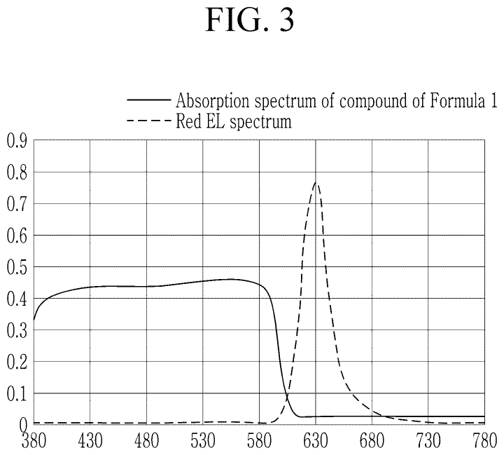

FIG. 3 illustrates a light emission spectrum of a red light emitting device and an absorption spectrum (or a light absorption spectrum) of the compound represented by Chemical Formula 1. Referring to FIG. 3, the compound represented by Chemical Formula 1 may be to absorb light with a wavelength of 600 nm or less while not substantially (e.g., hardly) absorbing light of a red wavelength, so that the reflectance of external light is reduced without reducing the luminous efficiency.

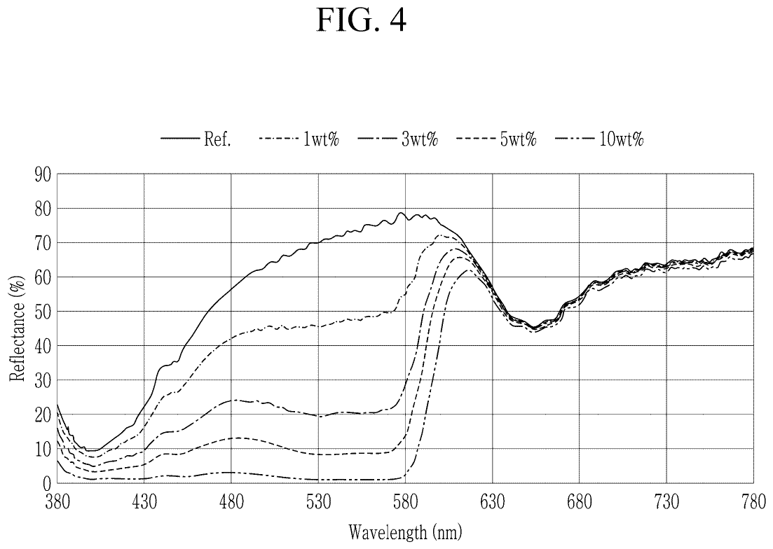

Table 1 and FIG. 4 show reflectance of the light emitting device according to a content (e.g., amount) of the compound of Chemical Formula 1 included in the red auxiliary layer.

TABLE 1

| Content | Reflectance (SCI) | Decrease rate |
|---|---|---|
| 0 wt % | 70.5% | 0.0% |
| 1 wt % | 51.8% | −26.6% |
| 3 wt % | 30.3% | −57.1% |
| 5 wt % | 20.0% | −71.6% |
| 10 wt % | 11.4% | −83.9% |

Referring to Table 1 and FIG. 4, it may be seen that the reflectance of the light emitting device is decreased as the content (e.g., amount) of the compound of Chemical Formula 1 is increased. Therefore, reflection of external light may be effectively prevented or reduced.

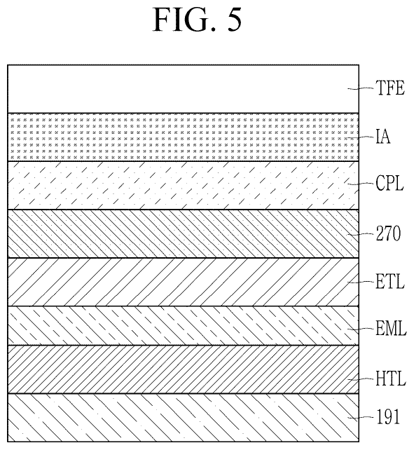

In an embodiment, an inorganic absorption layer IA may be further included between the second electrode 270 and the capping layer CPL or between the capping layer CPL and the encapsulation layer TFE. The inorganic absorption layer IA may include bismuth, and the inorganic absorption layer IA may reduce reflectance by absorbing external light. FIG. 5 illustrates the light emitting device including the inorganic absorption layer IA between the capping layer CPL and the encapsulation layer TFE. As shown in FIG. 5, even in a case of the light emitting device including the inorganic absorption layer IA, when a light absorbing material is included in the red auxiliary layer RA, the reflectance may be reduced.

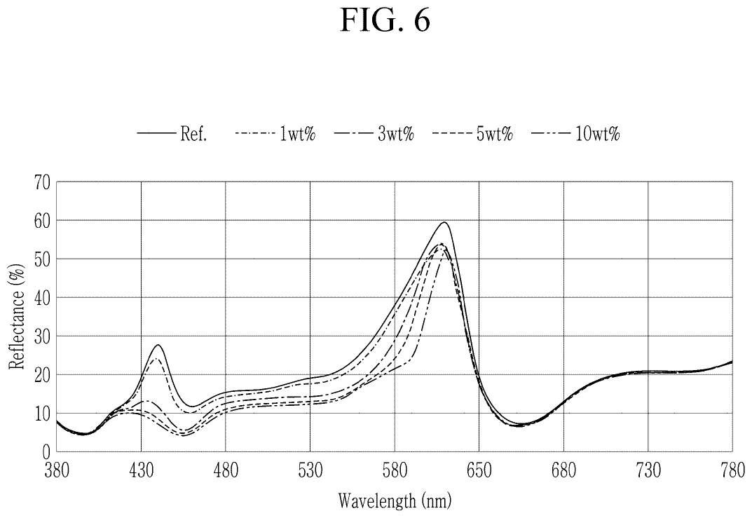

FIG. 6 shows the reflectance of the light emitting device according to the content (e.g., amount) of the compound of Chemical Formula 1 included in the red auxiliary layer RA in the light emitting device including the inorganic absorption layer IA shown in FIG. 5. Referring to FIG. 6, even in a case of the light emitting device including the inorganic absorption layer IA, it may be seen that reflectance is decreased as the content (e.g., amount) of the compound of Chemical Formula 1 included in the red auxiliary layer RA is increased.

In an embodiment, the green auxiliary layer GA or the green light emitting layer GE may include a yellow dye and/or a green dye. The yellow dye may be at least one compound represented by Chemical Formula 3 or 4, and the green dye may be at least one compound represented by Chemical Formula 5 or 6. In this case, a content (e.g., amount) of the dye within the green auxiliary layer GA or the green light emitting layer GE may be 1 wt % to 50 wt % based on a total weight of the green auxiliary layer GA or the green light emitting layer GE including the dye.

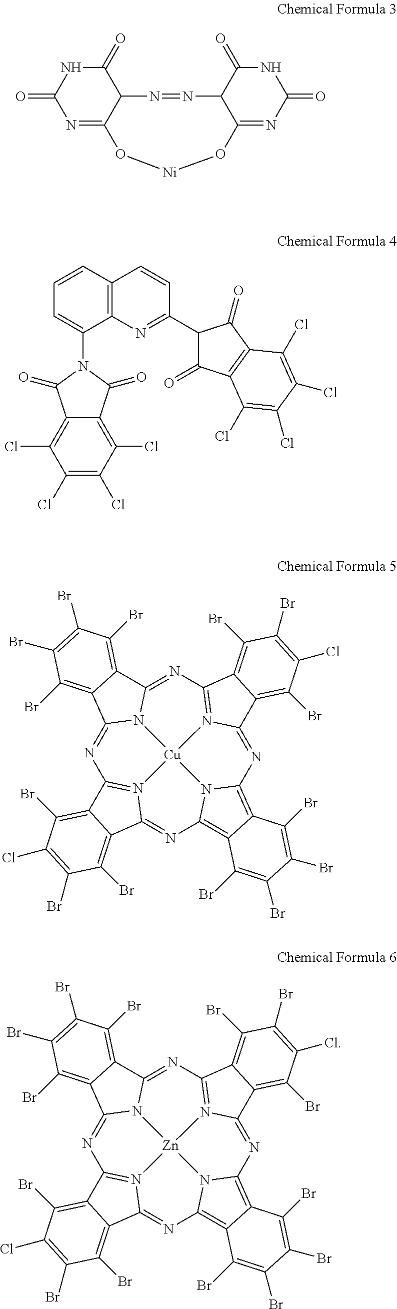

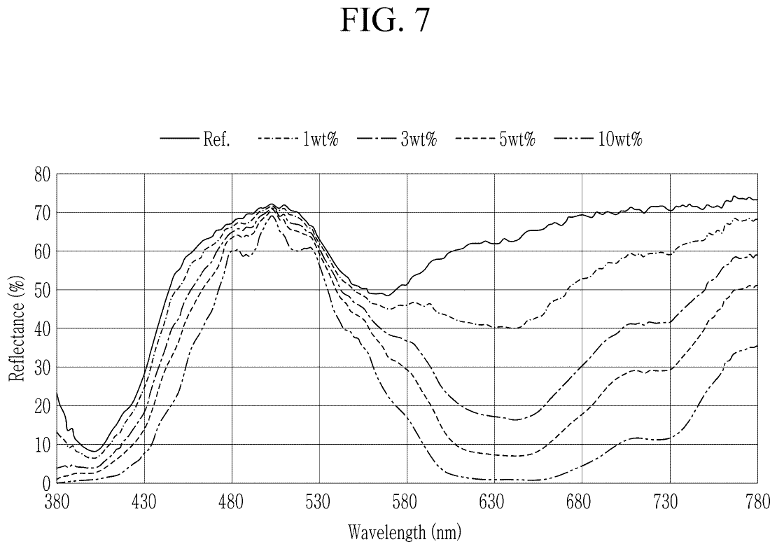

Table 2 and FIG. 7 show reflectance of the light emitting device according to a content (e.g., amount) of a compound of Chemical Formula 3 included in the green auxiliary layer.

TABLE 2

| Content | Reflectance (SCI) | Decrease rate |
|---|---|---|
| 0 wt % | 58.0% | 0.0% |
| 1 wt % | 52.5% | −9.5% |
| 3 wt % | 44.9% | −22.6% |
| 5 wt % | 39.9% | −31.2% |
| 10 wt % | 32.5% | −44.0% |

Referring to Table 2 and FIG. 7, it may be seen that the reflectance of the light emitting device is decreased as the content (e.g., amount) of the compound of Chemical Formula 3 is increased. Therefore, reflection of external light may be effectively prevented or reduced.

In an embodiment, the blue light emitting layer BE may include at least one compound represented by Chemical Formula 3, 4, 7, or 8. In this case, a content (e.g., amount) of the compound within the blue light emitting layer BE may be 1 wt % to 50 wt % based on a total weight of the blue light emitting layer BE.

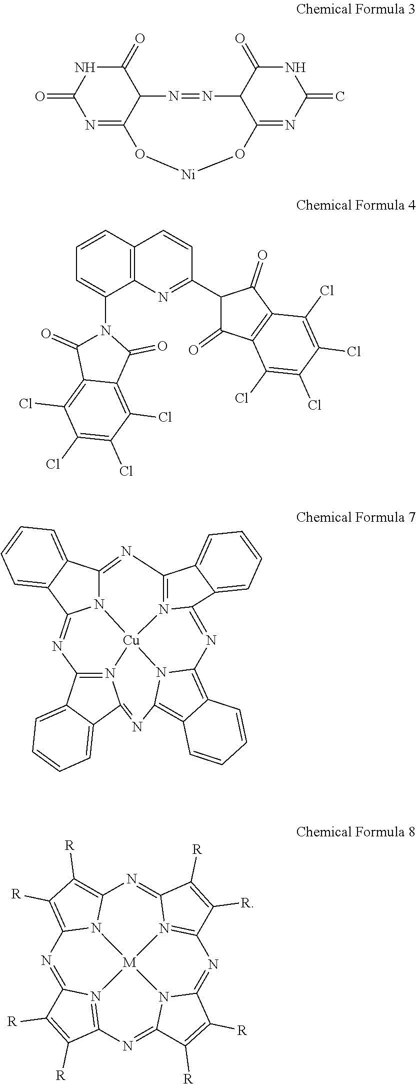

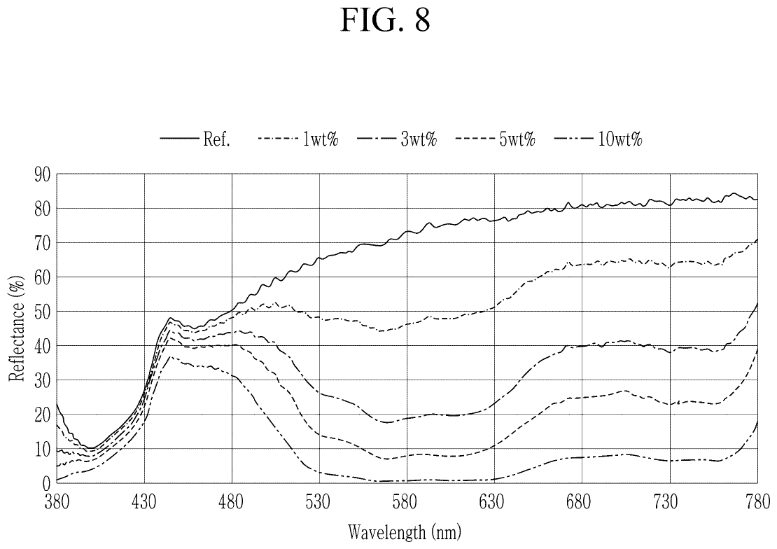

Table 3 and FIG. 8 show reflectance of the light emitting device according to a content (e.g., amount) of the compound represented by Chemical Formula 7 included in the blue light emitting layer.

TABLE 3

| Content | Reflectance (SCI) | Decrease rate |
|---|---|---|
| 0 wt % | 67.7% | 0.0% |
| 1 wt % | 47.9% | −29.2% |
| 3 wt % | 25.1% | −62.9% |
| 5 wt % | 14.2% | −79.0% |
| 10 wt % | 4.9% | −92.8% |

Referring to Table 3 and FIG. 8, it may be seen that the reflectance of the light emitting device is decreased as the content (e.g., amount) of the compound of Chemical Formula 7 is increased. Therefore, reflection of external light may be effectively prevented or reduced.

As described above, the embodiments in which the light absorbing material is included in the light emitting layer and/or the auxiliary layer of the light emitting device for emitting light of each color have been described, but the present disclosure is not limited thereto. In some embodiments, the light absorbing material may be included in a common layer such as the hole control layer and/or the electron control layer. In this case, the same light absorbing material may be included in the light emitting device for emitting light of each color. For example, the light emitting device according to the present embodiment may include one or more dyes (e.g., the compounds) represented by Chemical Formulas 8 to 11 in the hole control layer or the electron control layer. In this case, a content (e.g., amount) of the dye within the hole control layer or the electron control layer may be 1 wt % to 50 wt % based on a total weight of the hole control layer or the electron control layer including the dye.

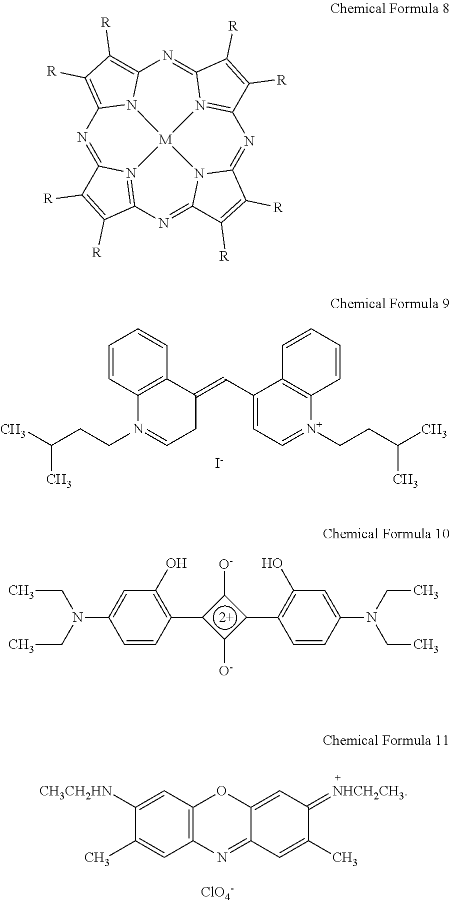

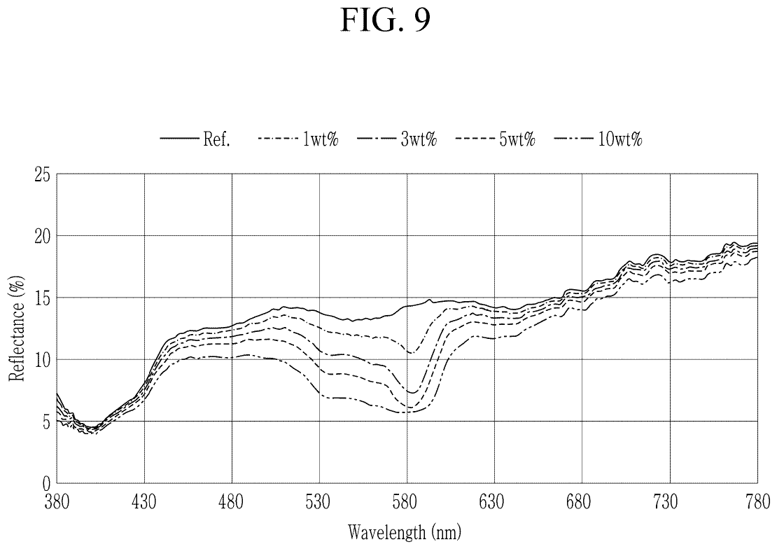

Table 4 and FIG. 9 show reflectance of the light emitting device according to the content (e.g., amount) of the compound of Formula 8 included in the hole control layer.

TABLE 4

| Content | Reflectance (SCI) | Decrease rate |
|---|---|---|
| 0 wt % | 13.7% | 0.0% |
| 1 wt % | 12.4% | −9.4% |
| 3 wt % | 10.7% | −22.4% |
| 5 wt % | 9.5% | −30.8% |
| 10 wt % | 7.9% | −42.8% |

Referring to Table 4 and FIG. 9, it may be seen that the reflectance of the light emitting device is decreased as the content (e.g., amount) of the compound of Chemical Formula 8 is increased. Therefore, reflection of external light may be effectively prevented or reduced. The compound of Chemical Formula 8 may be commonly included in the red light emitting device, the green light emitting device, and the blue light emitting device, and as may be seen from FIG. 9, reflectance is decreased in all wavelength regions.

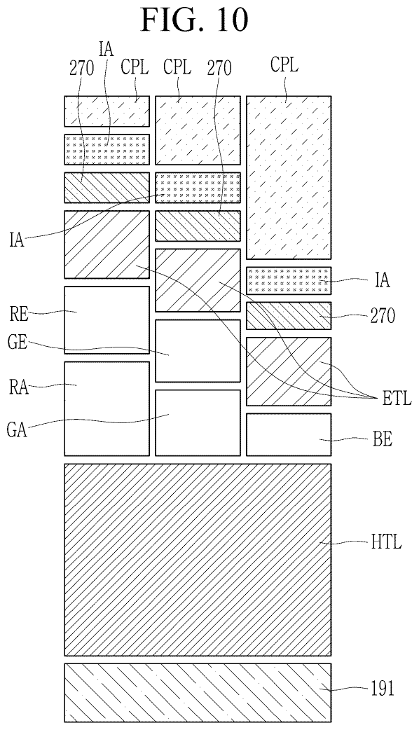

FIG. 10 shows a cross-sectional view for a light emitting device according to another embodiment, and is substantially the same as the embodiment of FIG. 2 except that the inorganic absorption layer IA is further included between the second electrode 270 and the capping layer CPL. A detailed description of the same component is omitted. The inorganic absorption layer IA may include bismuth.

According to an Embodiment 1 (or a first embodiment) in a structure of FIG. 10, the red auxiliary layer RA may include the compound of Chemical Formula 1, the green auxiliary layer GA may include the compound of Chemical Formula 3, and the blue light emitting layer BE may include the compound of Chemical Formula 8.

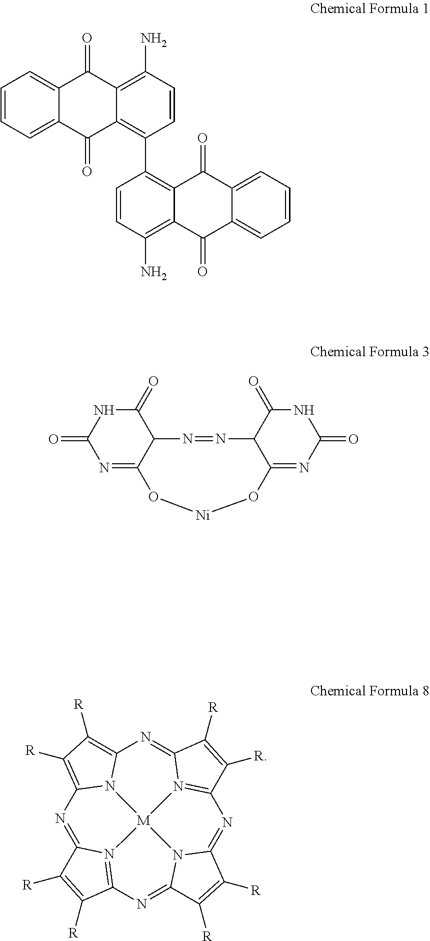

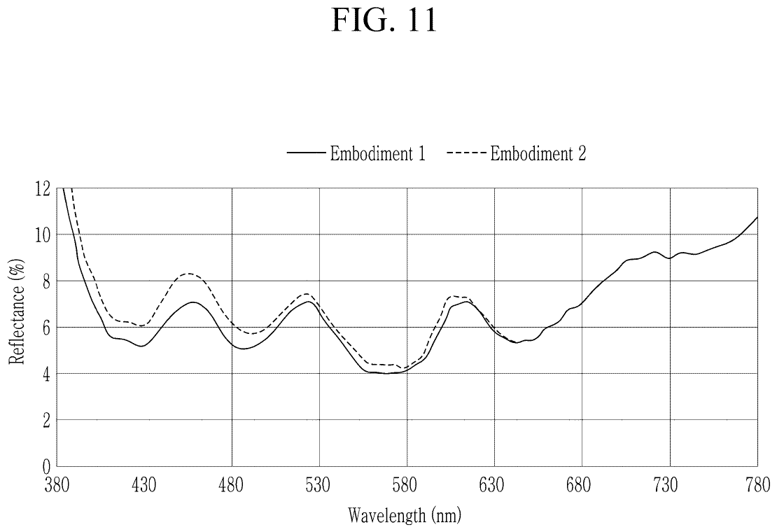

An optical characteristic of the Embodiment 1 is compared with an Embodiment 2 (or a second embodiment). Embodiment 2 has the structure of FIG. 10 but does not include (e.g., may exclude any of) the compound of Chemical Formula 1, the compound of Chemical Formula 3, or the compound of Chemical Formula 8 in the respective layer, and the optical characteristics of Embodiments 1 and 2 are shown in Table 5 and FIG. 11.

TABLE 5

| | Embodiment 1 | Embodiment 2 |
|---|---|---|
| Efficiency (Pol. ratio) | 123.6% | 123.6% |
| Reflectance (SCI) | 5.46% | 5.77% |
| Reflective color (CIE x) | 0.305 | 0.295 |
| Reflective color (CIE y) | 0.311 | 0.299 |

It may be seen that the Embodiment 1, in which the red auxiliary layer RA include the compound of Chemical Formula 1, the green auxiliary layer include the compound of Chemical Formula 3, and the blue light emitting layer include the compound of Chemical Formula 8, has a reflectance decrease of 0.31% compared with the Embodiment 2 that does not include the respective compounds.

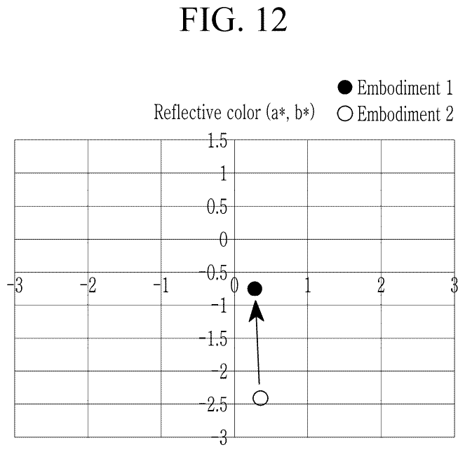

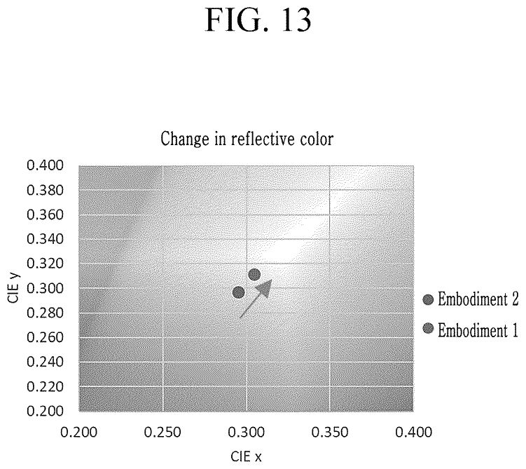

FIG. 12 is a measurement of reflective colors of the Embodiments 1 and 2, and FIG. 13 shows the reflective colors (or reflective color senses) of the Embodiments 1 and 2. Referring to FIGS. 12 and 13, it may be seen that the Embodiment 1 shows improved reflective color (or improved reflective color senses) compared with the Embodiment 2. For example, it may be seen that the light emitting device including a light absorbing dye and/or a light absorbing pigment according to the present embodiment reduces reflectance and has improved reflective color.

Because the light emitting device has an excellent or suitable low reflection characteristic, the light emitting device may be applied to a display device that does not include a separate polarization layer (e.g., is free of polarization layer or is polarization layer free). Hereinafter, one or more suitable structures of the display device including the light emitting device will be described. Similar to the one or more suitable embodiments described above, the light emitting device described below may include a light absorbing dye and/or a light absorbing pigment (e.g., does not include a separate color filter (e.g., is free of color filter or is color filter free)).

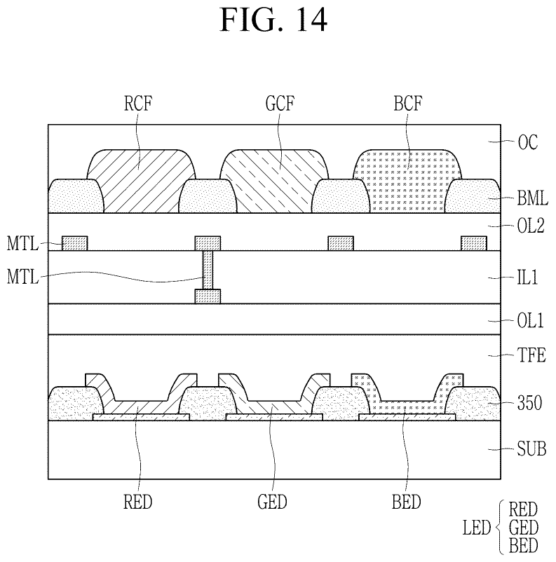

FIG. 14 schematically illustrates a cross-sectional view of the display device according to an embodiment.

Referring to FIG. 14, a plurality of the light emitting devices LED are disposed above or on the substrate SUB. Each light emitting device LED may be the red light emitting device RED, the blue light emitting device BED, or the green light emitting device GED, and description of these light emitting devices is the same as described above. For example, each light emitting device LED may include a light absorbing dye and/or a light absorbing pigment within the device.

A partition wall 350 may be disposed between light emitting devices LED, and the encapsulation layer TFE may be disposed on the light emitting device LED and the partition wall 350. A first organic film OL1, a first inorganic film IL1, and a second organic film OL2 may be disposed above or on the encapsulation layer TFE. According to an embodiment, portions of the first organic film OL1, the first inorganic film IL1, and the second organic film OL2 may be omitted (e.g., not be provided or may be removed (e.g., to form an opening therein)). As shown in FIG. 14, a metal layer MTL may be disposed on the first inorganic film IL1, and a portion of the metal layer MTL may be connected to the metal layer MTL disposed on the first organic film OL1 through an opening formed in the first inorganic film IL1. In an embodiment, the metal layer MTL may not be provided.

Light blocking members BML may be disposed on the second organic film OL2, and a red color filter RCF, a green color filter GCF, and a blue color filter BCF may be disposed between the light blocking members BML. Each color filter may be disposed to overlap the light emitting device emitting the same color. An overcoat layer OC may be disposed on the red color filter RCF, the green color filter GCF, and the blue color filter BCF. For example, the display device according to the embodiment of FIG. 14 may include a color filter disposed overlapping the light emitting device LED without including a polarization layer.

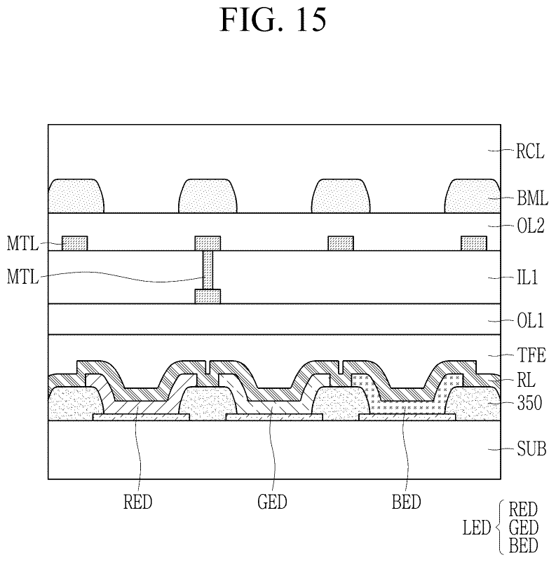

FIG. 15 is a cross-sectional view of a display device according to another embodiment. FIG. 15 is substantially the same as the embodiment of FIG. 14 except that FIG. 15 does not include a color filter CF, but further includes a low-reflection inorganic layer RL disposed on the light emitting device LED, and includes a reflection control layer RCL instead of the overcoat layer OC. A detailed description of the same components is not provided again. In the present embodiment shown in FIG. 15, the low-reflection inorganic layer RL disposed on the light emitting device LED is further included. Accordingly, the reflectance may be further reduced. In the embodiment of FIG. 15, each light emitting device LED may include a light absorbing dye and/or a light absorbing pigment within the device. Therefore, the reflectance may be reduced by the light emitting device LED, and the reflectance may be reduced by the low-reflection inorganic layer RL. In addition, the reflection control layer RCL is utilized instead of the overcoat layer OC. The reflection control layer RCL may be to absorb external light and may reduce the reflectance by including a light absorbing dye and/or a light absorbing pigment. A structure of FIG. 15 is more economical (e.g., to produce) because the number of masks utilized (e.g., needed) in the manufacturing process is less than that of FIG. 14.

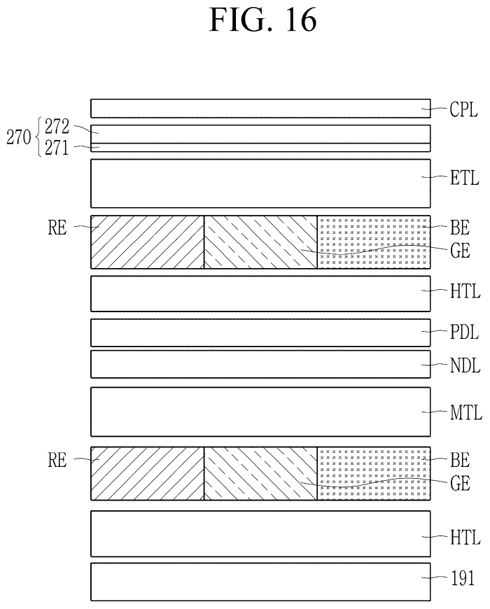

FIG. 16 shows a tandem structure in which light emitting devices are stacked. Referring to FIG. 16, the hole control layer HTL, the red light emitting layer RE, the green light emitting layer GE, and the blue light emitting layer BE may be disposed above or on the first electrode 191. In some embodiments, the red auxiliary layer and the green auxiliary layer may be further included. The metal layer MTL may be disposed above or on the light emitting layer, and an N-doped layer NDL and a P-doped layer PDL may be disposed above or on the metal layer MTL. Thereafter, the hole control layer HTL may be disposed, and the red light emitting layer RE, the green light emitting layer GE, and the blue light emitting layer BE may be disposed again. Next, the electron control layer ETL may be disposed, and the second electrode 270 may be disposed. The second electrode 270 may include a first layer 271 and a second layer 272, and the first layer 271 may include Yb and the second layer 272 may include Ag and Mg. The capping layer CPL may be disposed above or on the second electrode 270. Also, in an embodiment of FIG. 16, each light emitting device may include a light absorbing dye and/or a light absorbing pigment to reduce the reflectance.

The use of “may” when describing embodiments of the present disclosure refers to “one or more embodiments of the present disclosure”. As used herein, the term “and/or” includes any and all combinations of one or more of the associated listed items. Throughout the disclosure, the expression, such as “at least one of a, b or c”, “at least one selected from a, b, and c”, “at least one selected from the group consisting of a, b, and c”, “at least one from among a, b, and c”, etc., indicates only a, only b, only c, both (e.g., simultaneously) a and b, both (e.g., simultaneously) a and c, both (e.g., simultaneously) b and c, all of a, b, and c, or variation(s) thereof.

As used herein, the singular forms, “a,” “an,” and “the” are intended to include the plural forms as well, unless the context clearly indicates otherwise.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic apparatus, the display device, and/or any other relevant devices or components according to embodiments of the present invention described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the present disclosure has been described with reference to embodiments of the present disclosure, it will be understood that the present disclosure should not be limited to these embodiments but one or more suitable changes and modifications can be made by those skilled in the art without departing from the spirit and scope of the present disclosure.

Accordingly, the technical scope of the present disclosure is not intended to be limited to the contents set forth in the detailed description of the specification, but is intended to be defined by the appended claims, and equivalents thereof.

What is claimed is:

1. A display device comprising:
a substrate; and
a light emitting device on the substrate,
wherein the light emitting device comprises:
a first electrode,
a red auxiliary layer on the first electrode,
a red light emitting layer on the red auxiliary layer, and
a second electrode on the red light emitting layer, and
the red light emitting layer and/or the red auxiliary layer comprises a compound represented by Chemical Formula 1 and/or a compound represented by Chemical Formula 2:

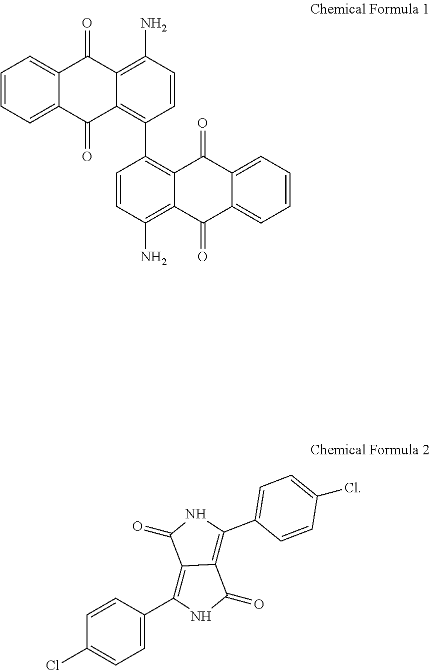 [SMILES: Nc1ccc(-c2ccc(N)c3c2C(=O)c2ccccc2C3=O)c2c1C(=O)c1ccccc1C2=O ; O=C1NC(c2ccc(Cl)cc2)=C2C(=O)NC(c3ccc(Cl)cc3)=C12]

2. The display device of claim 1, wherein an amount of the compound represented by Chemical Formula 1 and/or the compound represented by Chemical Formula 2 in the red light emitting layer and/or the red auxiliary layer is 1 wt % to 50 wt % based on a total weight of the red light emitting layer and/or the red auxiliary layer.

3. The display device of claim 1, wherein the light emitting device further comprises:
a capping layer on the second electrode; and
an encapsulation layer on the capping layer.

4. The display device of claim 3, wherein the light emitting device further comprises an inorganic absorption layer arranged between the capping layer and the encapsulation layer or arranged between the capping layer and the second electrode, and
the inorganic absorption layer comprises bismuth.

5. The display device of claim 1, wherein the display device is free of polarization layer.

6. The display device of claim 1, wherein the display device is free of color filter.

7. The display device of claim 3, further comprising:
a reflection control layer on the encapsulation layer; and
a low-reflection inorganic layer on the light emitting device,
wherein the reflection control layer comprises a pigment and/or a dye.

8. A display device comprising:
a substrate; and
a light emitting device on the substrate,
wherein the light emitting device comprises:
a first electrode,
a green auxiliary layer on the first electrode,
a green light emitting layer on the green auxiliary layer, and
a second electrode on the green light emitting layer, and
the green light emitting layer and/or the green auxiliary layer comprises at least one selected from compounds represented by Chemical Formula 3 to Chemical Formula 6:

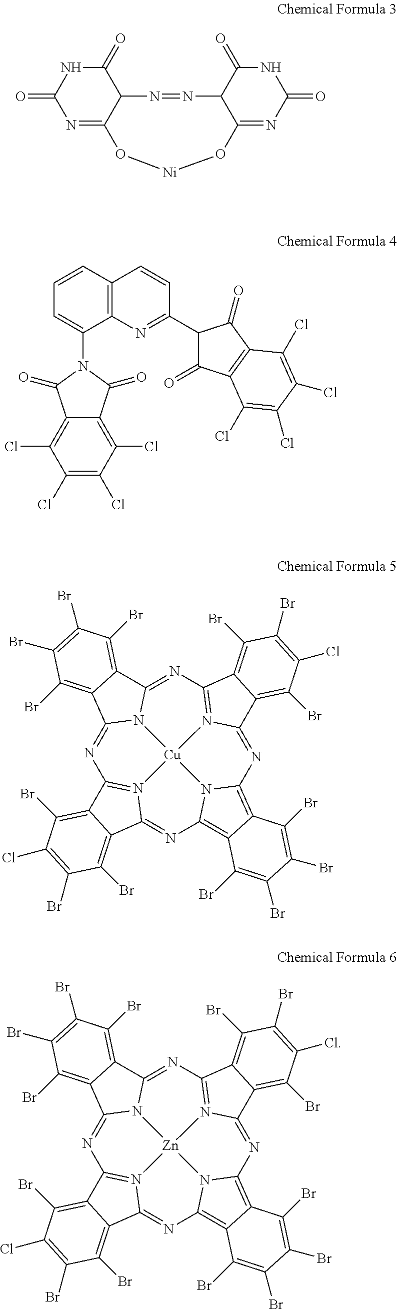

9. The display device of claim 8, wherein the at least one selected from the compounds represented by Chemical Formula 3 to Chemical Formula 6 in the green light emitting layer and/or the green auxiliary layer is 1 wt % to 50 wt % in amount based on a total weight of the green light emitting layer and/or the green auxiliary layer.

10. The display device of claim 8, wherein the light emitting device further comprises:
a capping layer on the second electrode; and
an encapsulation layer on the capping layer.

11. The display device of claim 10, wherein the light emitting device further comprises an inorganic absorption layer between the capping layer and the encapsulation layer or between the capping layer and the second electrode, and
the inorganic absorption layer comprises bismuth.

12. The display device of claim 8, wherein the display device is free of polarization layer.

13. The display device of claim 8, wherein the display device is free of color filter.

14. The display device of claim 10, further comprising:
a reflection control layer on the encapsulation layer; and
a low-reflection inorganic layer on the light emitting device,
wherein the reflection control layer comprises a pigment and/or a dye.

15. A display device comprising:
a substrate; and
a light emitting device on the substrate,
wherein the light emitting device comprises:
a first electrode,
a blue light emitting layer on the first electrode, and
a second electrode on the blue light emitting layer, and
the blue light emitting layer comprises at least one selected from compounds represented by Chemical Formula 3, Chemical Formula 4, Chemical Formula 7, or Chemical Formula 8:

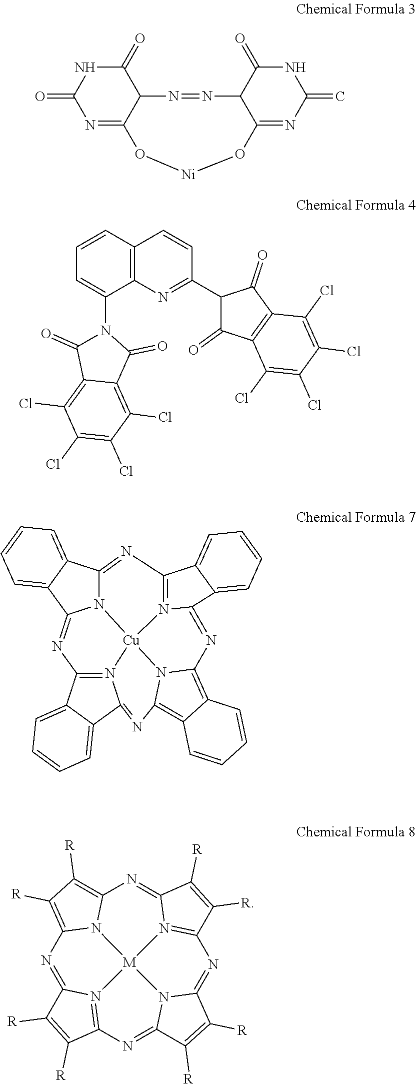

16. The display device of claim 15, wherein an amount of the at least one selected from compounds represented by Chemical Formula 3, Chemical Formula 4, Chemical Formula 7, and Chemical Formula 8 is 1 wt % to 50 wt % based on a total weight of the blue light-emitting layer.

17. A display device comprising:
a substrate; and
a plurality of light emitting devices on the substrate,
wherein the plurality of light emitting device comprise:
a first electrode,
a hole control layer on the first electrode,
a respective one of a red light emitting layer, a green light emitting layer, or a blue light emitting layer on the hole control layer,
an electron control layer on the red light emitting layer, the green light emitting layer, and the blue light emitting layer, and
a second electrode on the electron control layer, and
wherein the electron control layer or the hole control layer comprises at least one selected from compounds represented by Chemical Formula 8 to Chemical Formula 11:

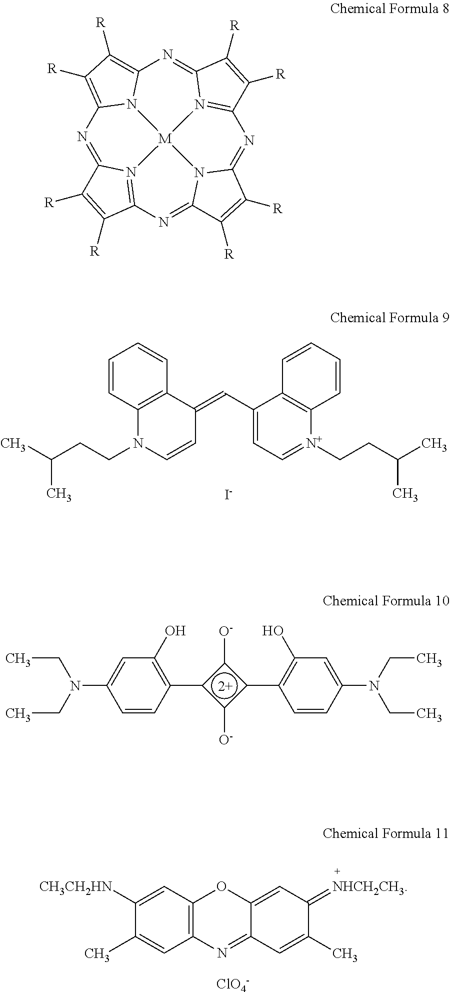

18. The display device of claim 17, wherein an amount of the at least one selected the compounds represented by Chemical Formula 8 to Chemical Formula 11 in the electron control layer and/or the hole control layer is 1 wt % to 50 wt % based on a total weight of the electron control layer and/or the hole control layer.

19. A display device comprising:
a substrate; and
a plurality of light emitting devices on the substrate,
wherein the plurality of light emitting device comprise:
a first electrode,
a hole control layer on the first electrode,
a red light emitting layer, a green light emitting layer, and a blue light emitting layer respectively arranged on the hole control layer,
an electron control layer on the red light emitting layer, the green light emitting layer, and the blue light emitting layer,
a second electrode on the electron control layer,
a red auxiliary layer between the red light emitting layer and the hole control layer, and
a green auxiliary layer between the green light emitting layer and the hole control layer,
the red auxiliary layer comprising a compound represented by Chemical Formula 1, the green auxiliary layer comprising a compound represented by Chemical Formula 3, and the blue light emitting layer comprising a compound represented by Chemical Formula 8:

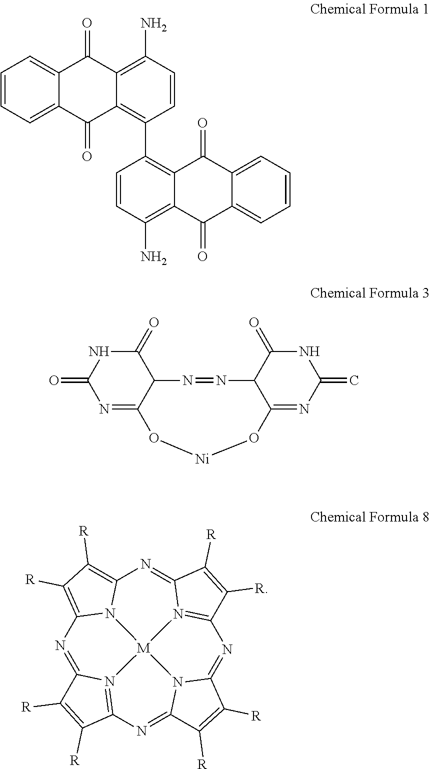

20. The display device of claim 19, wherein the display device is free of both polarization layer and color filter.
